(19) United States
(12) Patent Application Publication
(10) Pub. No.: US 2012/0300401 A1
(43) Pub. Date: Nov. 29, 2012

(54) ELECTRONIC DEVICE WITH HEAT DISSIPATION DEVICE

(75) Inventors: HUNG-YI WU, Tu-Cheng (TW); LEI LIU, Shenzhen City (CN)

(73) Assignees: HON HAI PRECISION INDUSTRY CO., LTD., Tu-Cheng (TW); HONG FU JIN PRECISION INDUSTRY (ShenZhen) CO. LTD., Shenzhen City (CN)

(21) Appl. No.: 13/233,037

(22) Filed: Sep. 15, 2011

(30) Foreign Application Priority Data
May 27, 2011 (CN) 201110139897.2

(51) Int. Cl. H05K 7/20

(52) U.S. Cl. 361/697

(57) ABSTRACT

An electronic device includes an expansion card, an electronic component attached on the expansion card, and a heat dissipation device attached to the expansion card to cool the component. The heat dissipation device includes a heat sink, a fixing member abuts the heat sink, and a fan fixed to the fixing member. The fixing member includes a frame, and two resilient latching arms extending from two opposite sides of the frame. The latching arms are detachably latched to the expansion card. The fan is fixed to a side of the frame opposite to the arms.

### BACKGROUND

1. Technical Field

The present disclosure relates to an electronic device having a heat dissipation device for dissipating heat for an electronic component.

2. Description of Related Art

Expansion cards may include a plurality of components which generate considerable heat. Fans may be employed and fixed to expansion cards using screws to dissipate the heat. However, it is time-consuming to assemble or disassemble the fan to or from an expansion card.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an electronic device, the electronic device including an expansion card, a heat sink, a fixing member, and a fan.

FIG. 2 is an enlarged, isometric view of the fixing member of FIG. 1.

FIG. 3 is a partially assembled, isometric view of the electronic device of FIG. 1.

FIG. 4 is an assembled, isometric view of the electronic device of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

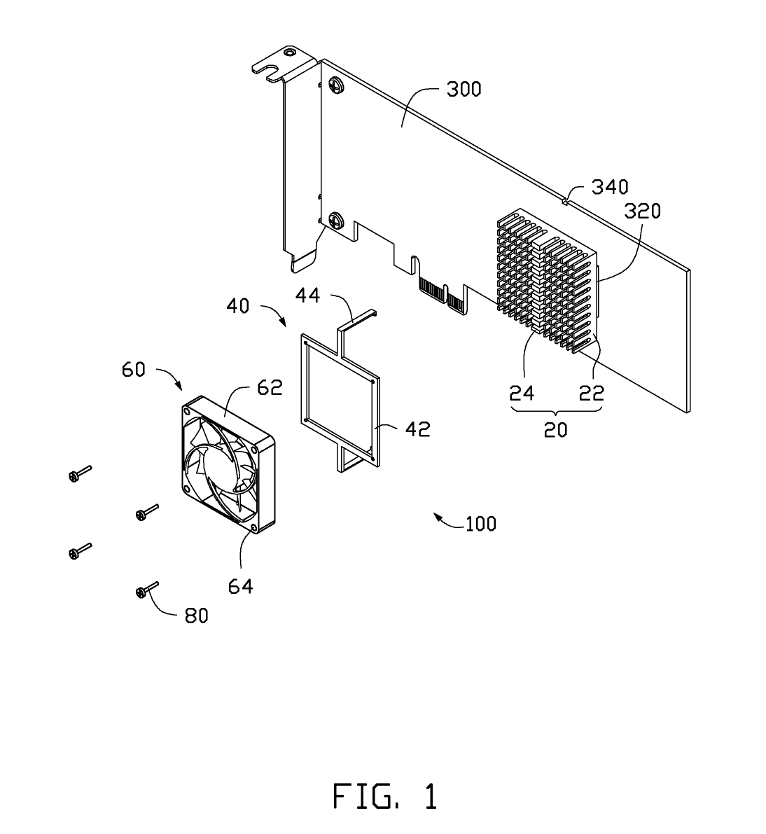

Referring to FIG. 1, an exemplary embodiment of an electronic device includes an expansion card 300, and a heat dissipation device 100. An electronic component 320 is mounted on the expansion card 300. Two cutouts 340 are respectively defined in two opposite edges of the expansion card 300 and adjacent the component 320. The heat dissipation device 100 includes a heat sink 20, a fixing member 40, a fan 60, and four fasteners 80.

The heat sink 20 includes a base 22, and a plurality of fins 24 extending perpendicularly from the base 22. The heat sink 20 is attached to the expansion card 300, with a sidewall of the base 22 opposite to the fins 24 fixed to the component 320 by conventional means.

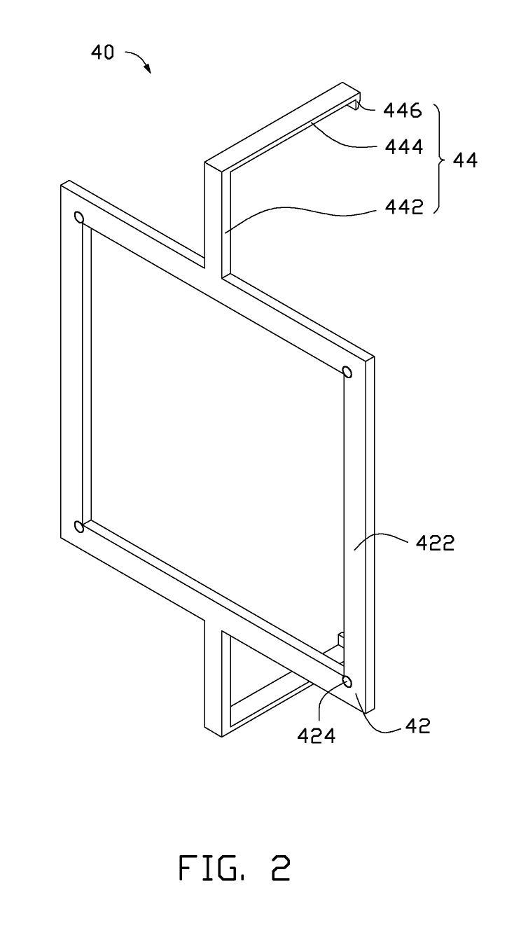

Referring to FIG. 2, the fixing member 40 includes a rectangular frame 42 consisting of four plates 422, and a pair of L-shaped resilient latching arms 44 extending from two opposite plates 422 and configured to latch the cutouts 340. Four fastening holes 424 are defined in four corners of the frame 42, respectively. Each latching arm 44 includes a first pole 442 connecting with the frame 42, and a second pole 444 perpendicularly extending from a distal end of the first pole 442. A latch 446 is formed at a distal end of each second pole 444. A slanted guiding wall is formed at an outside of each latch 446. In the embodiment, the fixing member 40 may be made of plastic or steel and is configured to be resilient.

The fan 60 is rectangular. Four through holes 64 are defined in four corners of the fan 60, respectively.

In the embodiment, the fasteners 80 are screws.

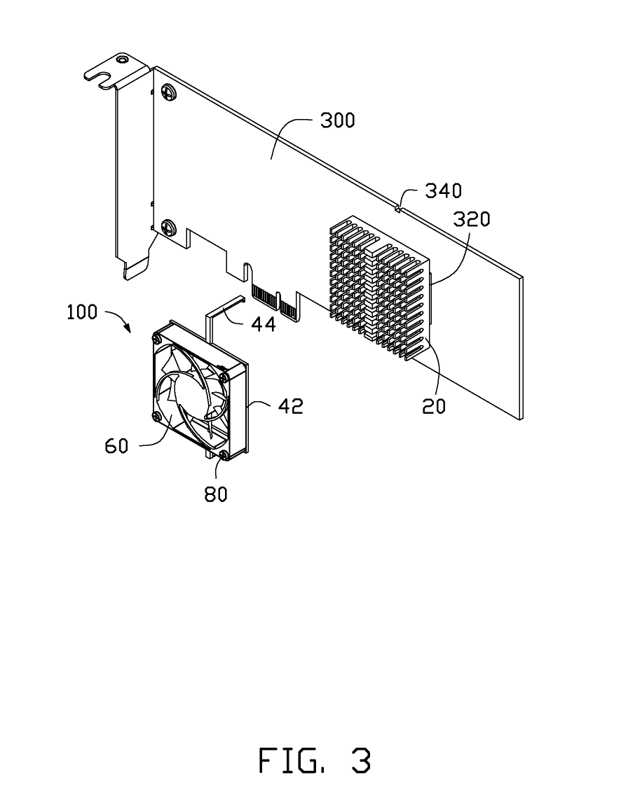

Referring to FIG. 3, attaching the fan 60 to the fixing member 40 opposite to the arms 44, with the fasteners 80 extending through the through holes 64 to engage in the fastening holes 424.

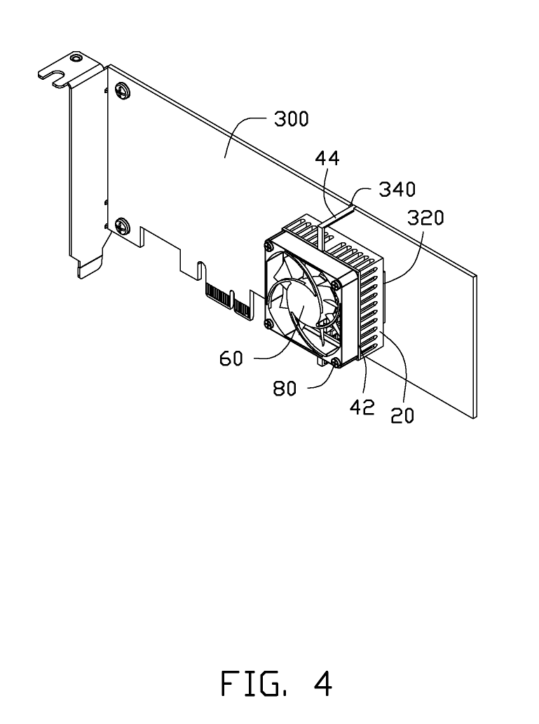

Referring to FIG. 4, the fan 60 and the fixing member 40 are attached to the expansion card 300. The second poles 444 engage in the cutouts 340, with a side of the frame 42 opposite to the fan 60 abutting distal ends of the fins 24, and the latches 446 deformably abutting a sidewall of the expansion card 300 opposite to the component 320.

To detach the fan 60 and the fixing member 40 from the expansion card 300, the latching arms 44 are flexed to disengage the latches 446 from the cutouts 340.

It is to be understood, however, that even though numerous characteristics and advantages of the embodiments have been set forth in the foregoing description, together with details of the structure and function of the embodiments, the present disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A heat dissipation device for dissipating heat for an electronic component mounted on an expansion card, the heat dissipation device comprising:
a heat sink for being attached to the expansion card and contacting the component;
a fixing member comprising a frame abutting the heat sink, and two resilient latching arms extending from the frame to detachably latch with the expansion card; and
a fan fixed to a side of the frame opposite to the fan.

2. The heat dissipation device of claim 1, wherein the frame is rectangular and four fastening holes are defined in four corners of the frame, four through holes are defined in four corners of the fan, four fasteners extend through the through holes to engage in the fastening holes, respectively.

3. The heat dissipation device of claim 1, wherein the two latching arms are L-shaped , each arm comprises a first pole perpendicularly extending from the frame, a second pole perpendicularly extending from a distal end of the first pole away from the fan, a latch is formed at a distal end of the second pole to detachably latch with a sidewall of the expansion card opposite to the component.

4. The heat dissipation device of claim 1, wherein the fixing member is integrally made of resilient material.

5. An electronic device comprising:
an expansion card;
an electronic component attached on the expansion card; and
a heat dissipation device attached to the expansion card to cool the component;
wherein the heat dissipation device comprises a heat sink attached to the expansion card and contacting the component, a fixing member abuts the heat sink and detachably attached to the expansion card, and a fan fixed to a side of the fixing member opposite to the heat sink.

6. The electronic device of claim 5, wherein two cutouts are defined in two opposite sides of the expansion card beside the component, the fixing member comprises a frame, and two resilient latching arms extending from two opposite sides of the frame along a same direction, the arms engaged into the cutouts of the expansion card and is blocked by the expansion card.

7. The electronic device of claim 6, wherein the frame is rectangular and comprises four fixing plates connecting with each other forming the frame, four fastening holes are defined in four corners of the frame, four through holes are defined in four corners of the fan, four fasteners extend through the through holes to engage in the fastening holes.

8. The electronic device of claim 6, wherein the two latching arms are L-shaped.

9. The electronic device of claim 8, wherein each arm comprises a first pole perpendicularly extending from the frame, a second pole perpendicularly extending from a distal end of the first pole away from the fan, a latch is formed at a distal end of each second pole and detachably latch with a sidewall of the expansion card opposite to the element.

10. The electronic device of claim 6, wherein each cutout extends to an edge portion of the expansion card.
